(19) United States
(12) Patent Application Publication
(10) Pub. No.: US 2025/0349736 A1
(43) Pub. Date: Nov. 13, 2025

(54) METHOD FOR MANUFACTURING NITRIDE SEMICONDUCTOR DEVICE

(71) Applicant: SUMITOMO ELECTRIC INDUSTRIES, LTD., Osaka (JP)

(72) Inventor: Yukihiro TSUJI, Osaka (JP)

(21) Appl. No.: 19/191,469

(22) Filed: Apr. 28, 2025

(30) Foreign Application Priority Data
May 8, 2024 (JP) 2024-075766

(51) Int. Cl. H01L 23/544; H01L 21/02; H01L 21/027; H01L 21/306; H10D 30/01

(52) U.S. Cl. CPC H01L 23/544; H01L 21/0254; H01L 21/0274; H01L 21/30617; H01L 2223/54426; H10D 30/015

(57) ABSTRACT

A method for manufacturing a nitride semiconductor device includes forming an insulating film having a first opening on an upper surface of a first nitride semiconductor layer, the upper surface having a nitrogen polarity, forming a second nitride semiconductor layer on the upper surface inside the first opening, and forming an alignment mark by roughening an upper surface of the second nitride semiconductor layer by a wet etching using an alkaline solution.

### CROSS-REFERENCE TO RELATED APPLICATIONS

This application is based upon and claims priority to Japanese Patent Application No. 2024-075766, filed on May 8, 2024, the entire contents of which are incorporated herein by reference.

### TECHNICAL FIELD

The present disclosure relates to methods for manufacturing nitride semiconductor devices.

### BACKGROUND

When manufacturing a nitride semiconductor device, an alignment is performed using an alignment mark.

Related art include International Publication Pamphlet No. WO 2007/080795, and Japanese Laid-Open Patent Publication No. 2018-163928, for example.

In recent years, as the size of the nitride semiconductor devices continue to decrease, there are increasing demands to further improve an alignment accuracy among a plurality of constituent elements included in the nitride semiconductor devices.

### SUMMARY

A method for manufacturing a nitride semiconductor device according an aspect of the present disclosure includes forming an insulating film having a first opening on an upper surface of a first nitride semiconductor layer, the upper surface having a nitrogen polarity; forming a second nitride semiconductor layer on the upper surface inside the first opening; and forming an alignment mark by roughening an upper surface of the second nitride semiconductor layer by a wet etching using an alkaline solution.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view (part 1) illustrating a method for manufacturing a nitride semiconductor device according to an embodiment;

FIG. 2 is a cross sectional view (part 2) illustrating the method for manufacturing the nitride semiconductor device according to the embodiment;

FIG. 3 is a cross sectional view (part 3) illustrating the method for manufacturing the nitride semiconductor device according to the embodiment;

FIG. 4 is a cross sectional view (part 4) illustrating the method for manufacturing the nitride semiconductor device according to the embodiment;

FIG. 5 is a cross sectional view (part 5) illustrating the method for manufacturing the nitride semiconductor device according to the embodiment;

FIG. 6 is a sectional view (part 6) illustrating the method for manufacturing the nitride semiconductor device according to the embodiment;

FIG. 7 is a cross sectional view (part 7) illustrating the method for manufacturing the nitride semiconductor device according to the embodiment;

FIG. 8 is a cross sectional view (part 8) illustrating the method for manufacturing the nitride semiconductor device according to the embodiment;

FIG. 9 is a cross sectional view (part 9) illustrating the method for manufacturing the nitride semiconductor device according to the embodiment;

FIG. 10 is a cross sectional view (part 10) illustrating the method for manufacturing the nitride semiconductor device according to the embodiment;

FIG. 11 is a cross sectional view (part 11) illustrating the method for manufacturing the nitride semiconductor device according to the embodiment;

FIG. 12 is a cross sectional view (part 12) illustrating the method for manufacturing the nitride semiconductor device according to the embodiment;

FIG. 13 is a cross sectional view (part 13) illustrating the method for manufacturing the nitride semiconductor device according to the embodiment;

FIG. 14 is a cross sectional view (part 14) illustrating the method for manufacturing the nitride semiconductor device according to the embodiment;

FIG. 15 is a cross sectional view (part 15) illustrating the method for manufacturing the nitride semiconductor device according to the embodiment;

FIG. 16 is a cross sectional view (part 16) illustrating the method for manufacturing the nitride semiconductor device according to the embodiment;

FIG. 17 is a cross sectional view (part 17) illustrating the method for manufacturing the nitride semiconductor device according to the embodiment;

FIG. 18 is a cross sectional view (part 1) illustrating a method for manufacturing a nitride semiconductor device using a metal alignment mark; and

FIG. 19 is a cross sectional view (part 2) illustrating the method for manufacturing the nitride semiconductor device using the metal alignment mark.

### DETAILED DESCRIPTION

### Description of Embodiments of the Present Disclosure

One object according to an aspect of the present disclosure is to provide a method for manufacturing a nitride semiconductor device capable of improving an alignment accuracy.

First, embodiments of the present disclosure will be described in the following.

[1] A method for manufacturing a nitride semiconductor device according to one aspect of the present disclosure includes forming an insulating film having a first opening on an upper surface of a first nitride semiconductor layer, the upper surface having a nitrogen polarity; forming a second nitride semiconductor layer on the upper surface inside the first opening; and forming an alignment mark by roughening an upper surface of the second nitride semiconductor layer by a wet etching using an alkaline solution.

The upper surface of the second nitride semiconductor layer is roughened to form a roughened alignment mark. The alignment mark can easily be detected if a layer formed thereon can transmit light used for detecting the alignment mark. Accordingly, when the alignment is performed a plurality of times to form a plurality of constituent elements included in the nitride semiconductor device, the position of the common alignment mark can be used as a reference. For this reason, it is possible to improve the alignment accuracy among the plurality of constituent elements included in the nitride semiconductor device.

[2] The method for manufacturing the nitride semiconductor device according to [1] above may further include forming a photosensitive film on the insulating film and the alignment mark; irradiating the photosensitive film with first light and detecting a position of the alignment mark from reflected light from the alignment mark; and forming a photosensitive region by irradiating a portion of the photosensitive film with second light, with reference to the detected position of the alignment mark. In this case, the photosensitive region can be formed with a high alignment accuracy.

[3] In the method for manufacturing the nitride semiconductor device according to [2] above, the first light may have a wavelength of 546 nm or more and 547 nm or less (e-line (green mercury)), and the second light may have a wavelength of 365 nm or more and 436 nm or less (i-line (ultraviolet mercury), h-line (violet mercury), g-line (blue mercury)). In this case, the position of the alignment mark can be detected without exposing the photosensitive film using the first light, and the photosensitive region can thereafter be formed in the photosensitive film using the second light.

[4] In the method for manufacturing the nitride semiconductor device according to any one of [1] to [3] above, the second nitride semiconductor layer may be a gallium nitride layer. In this case, the second nitride semiconductor layer can be formed with ease.

[5] In the method for manufacturing the nitride semiconductor device according to [4] above, the alignment mark may have an upper surface including a (10-1-1) plane of gallium nitride. When the second nitride semiconductor layer is a gallium nitride layer, the upper surface of the alignment mark is likely to include a (10-1-1) plane of gallium nitride. For example, when the upper surface of the second nitride semiconductor layer includes a (000-1) plane (−c plane), a (10-1-1) plane is exposed by a wet etching. The (10-1-1) plane is more likely to cause a diffuse reflection of light than the (000-1) plane (−c plane).

[6] In the method for manufacturing the nitride semiconductor device according to any one of [1] to [5] above, the alkaline solution may include potassium hydroxide or tetramethylammonium hydroxide. In this case, the upper surface of the second nitride semiconductor layer can easily be roughened.

[7] In the method for manufacturing the nitride semiconductor device according to any one of [1] to [6] above, the insulating film may have a second opening, and the method may further include forming a third nitride semiconductor layer inside the second opening simultaneously as forming the second nitride semiconductor layer. If the third nitride semiconductor layer is to be ultimately included in the nitride semiconductor device, it is unnecessary to provide an additional process of forming the second nitride semiconductor layer.

According to the present disclosure, it is possible to improve an alignment accuracy.

### Details of Embodiments of the Present Disclosure

Hereinafter, embodiments of the present disclosure will be described in detail, but the present disclosure is not limited thereto. In the present specification and the drawings, constituent elements having substantially the same functional configuration are designated by the same reference numerals, and a redundant description thereof may be omitted. Although negative indices in crystallography are usually represented by placing a bar “⁻” over the number, the present disclosure represents the negative indices in crystallography by placing a negative sign “−” before the number.

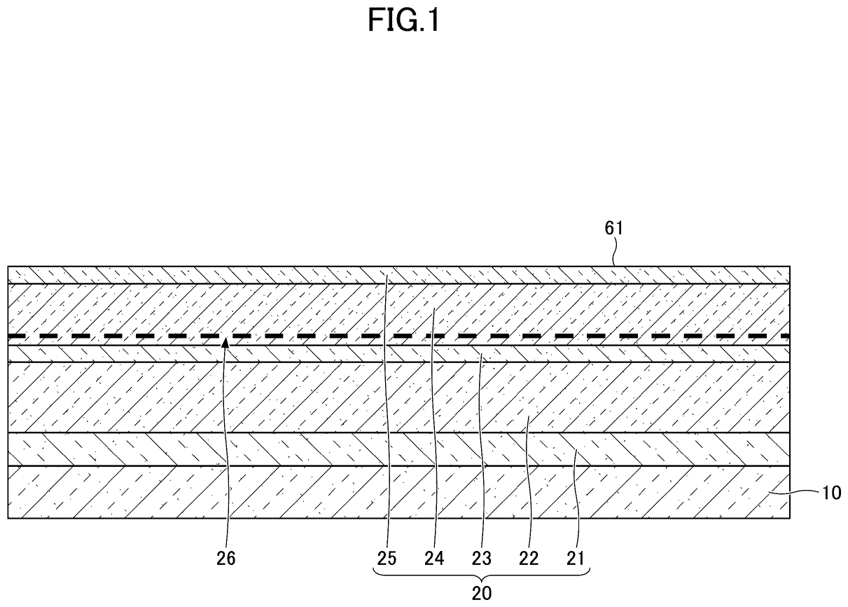

Embodiments of the present disclosure relate to methods for manufacturing a nitride semiconductor device including a high electron mobility transistor (HEMT). FIG. 1 through FIG. 17 are cross sectional views illustrating a method for manufacturing a nitride semiconductor device according to an embodiment.

First, as illustrated in FIG. 1, a nitride semiconductor layer 20 is formed on a substrate 10. The nitride semiconductor layer 20 can be formed by metal organic chemical vapor deposition (MOCVD) or molecular beam epitaxy (MBE), for example. When forming the nitride semiconductor layer 20, a buffer layer 21, a barrier layer 22, a spacer layer 23, a channel layer 24, and a cap layer are successively formed in this order. The nitride semiconductor layer 20 is an example of a first nitride semiconductor layer.

The substrate 10 is a semi-insulating silicon carbide (SiC) substrate, for example. In a case where the substrate 10 is a SiC substrate, an upper surface of the substrate 10 is a carbon (C) polar plane. In the case where the surface of the substrate 10 is a C polar plane, the nitride semiconductor layer 20 can be grown by crystal growth using a nitrogen (N) polar plane as a growth surface, and the nitride semiconductor layer 20 includes an upper surface 61 having a nitrogen polarity.

The buffer layer 21 is an aluminum nitride (AlN) layer, for example. The AlN layer has a thickness that is 1 nm or greater and 2000 nm or less, for example. The buffer layer 21 may include an AlN layer and a GaN layer or an aluminum gallium nitride (AlGaN) layer on the AlN layer.

The barrier layer 22 is an AlGaN layer, for example. A band gap of the barrier layer 22 is larger than a band gap of the channel layer 24. The barrier layer 22 has a thickness that is 1 nm or greater and 50 nm or less, for example. A composition of the barrier layer 22 is Al_{Y}Ga_{1-Y}N (0.15<=Y<=0.55), for example. A conductivity type of the barrier layer 22 is the n-type or undoped (i-type), for example. A scandium aluminum nitride (ScAlN) layer, an indium aluminum nitride (InAlN) layer, or an indium aluminum gallium nitride (InAlGaN) layer may be used in place of the AlGaN layer.

The spacer layer 23 is an AlN layer, for example. The spacer layer 23 has a thickness in a range that is 0.2 nm or greater and 5 nm or less, for example.

The channel layer 24 is a GaN layer, for example. The band gap of the channel layer 24 is smaller than the band gap of the barrier layer 22. The channel layer 24 has a thickness that is 1 nm or greater and 50 nm or less, for example. Strain is generated between the channel layer 24 and the barrier layer 22 due to the difference in lattice constants thereof, and strain is generated between the channel layer 24 and the spacer layer 23 due to the difference in lattice constants thereof. Such strain induces piezoelectric charges at an interfaces between the channel layer 24 and the barrier layer 22, and at an interface between the channel layer 24 and the spacer layer 23. As a result, a two-dimensional electron gas (2DEG) is generated in the channel layer 24 in a vicinity of the surface opposing the barrier layer 22, thereby forming a channel region 26. A conductivity type of the channel layer 24 is the n-type or undoped (i-type), for example.

The cap layer 25 is an AlGaN layer, for example. The cap layer 25 has a thickness that is 0.1 nm or greater and 10 nm or less, for example. The cap layer 25 may be omitted.

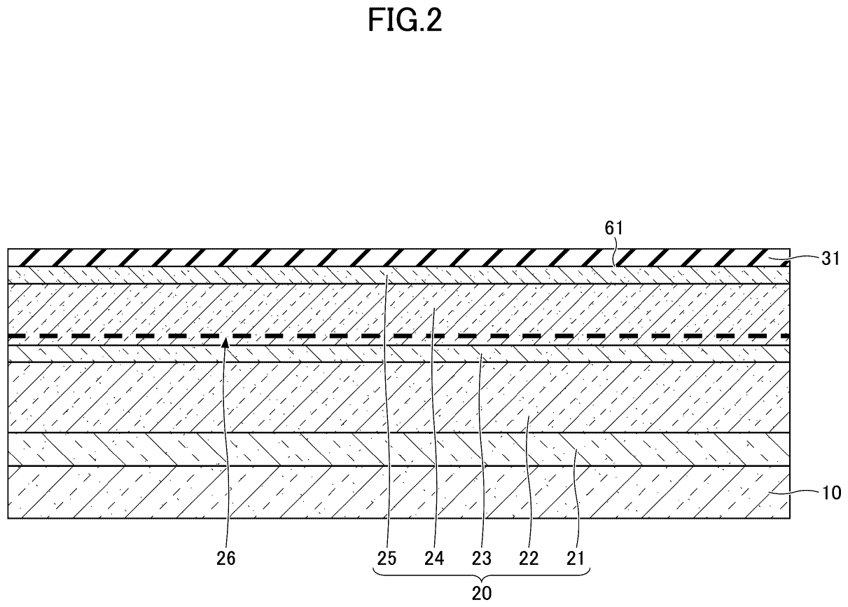

Next, as illustrated in FIG. 2, an insulating film 31 is formed on the nitride semiconductor layer 20. The insulating film 31 can be formed by plasma CVD or atomic layer deposition (ALD), for example. For example, a relative permittivity (or relative dielectric constant) of the insulating film 31 is higher than a relative permittivity of silicon dioxide (SiO₂). The insulating film 31 may be a high dielectric constant film. The insulating film 31 is a silicon nitride (SiN) film, for example. The insulating film 31 may be a dielectric oxide film or a dielectric oxynitride film. The dielectric oxide film or the dielectric oxynitride film may include at least one element selected from a group consisting of hafnium (Hf), lanthanum (La), and zirconium (Zr). In addition, the dielectric oxide film or the dielectric oxynitride film may include at least one element selected from a group consisting of silicon (Si) and aluminum (Al). For example, the insulating film 31 may be a hafnium silicate (HfSiOₓ) film, a hafnium aluminate (HfAlOₓ) film, a hafnium silicon oxynitride (HfSiON) film, or a hafnium aluminum oxynitride (HfAlON) film. The insulating film 31 has a thickness that is 1 nm or greater and 30 nm or less, for example.

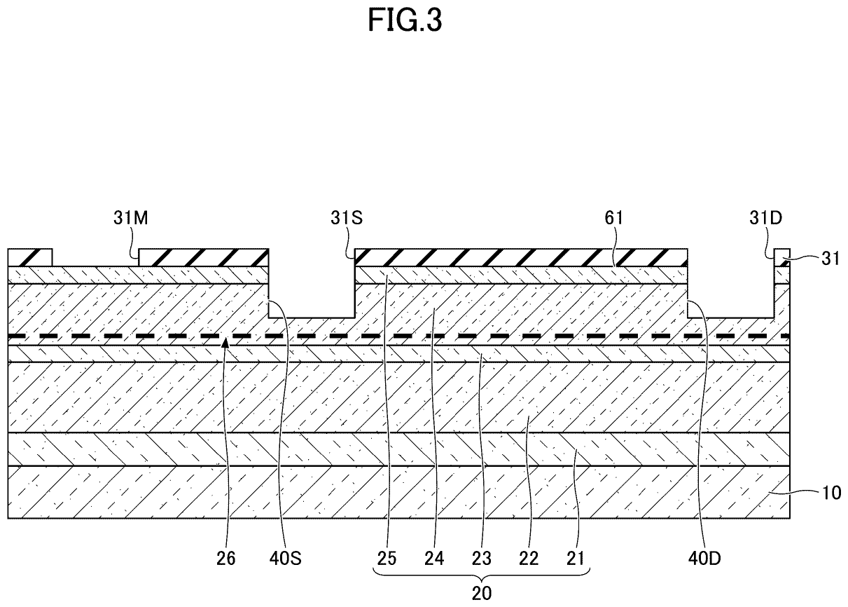

Next, as illustrated in FIG. 3, an opening 31M for an alignment mark, an opening 31S for a source, and an opening 31D for a drain are formed in the insulating film 31, and a recess 40S for the source and a recess 40D for the drain are formed in the nitride semiconductor layer 20. A bottom of the recess 40S and a bottom of the recess 40D may be closer to a lower surface of the nitride semiconductor layer 20 than to an upper surface of the channel layer 24. That is, the recess 40S and the recess 40D may be formed to a depth deeper than the upper surface of the channel layer 24. The bottom of the recess 40S and the bottom of the recess 40D may be in the channel layer 24, or in the spacer layer 23, or in the barrier layer 22. For example, the opening 31M is formed in a dicing region that disappears when performing a singulation, while the opening 31S and the opening 31D are formed in a chip region that remains after performing the singulation. The opening 31M is an example of a first opening, and the opening 31S and the opening 31D are examples of a second opening.

The opening 31M, the opening 31S, the opening 31D, the recess 40S, and the recess 40D can be formed by reactive ion etching (RIE) using a mask (not illustrated), for example. For example, a fluorine-based (F-based) gas is used as a reactive gas when forming the opening 31M, the opening 31S, and the opening 31D, and a chlorine-based (Cl-based) gas is used as the reactive gas when forming the recess 40S and the recess 40D.

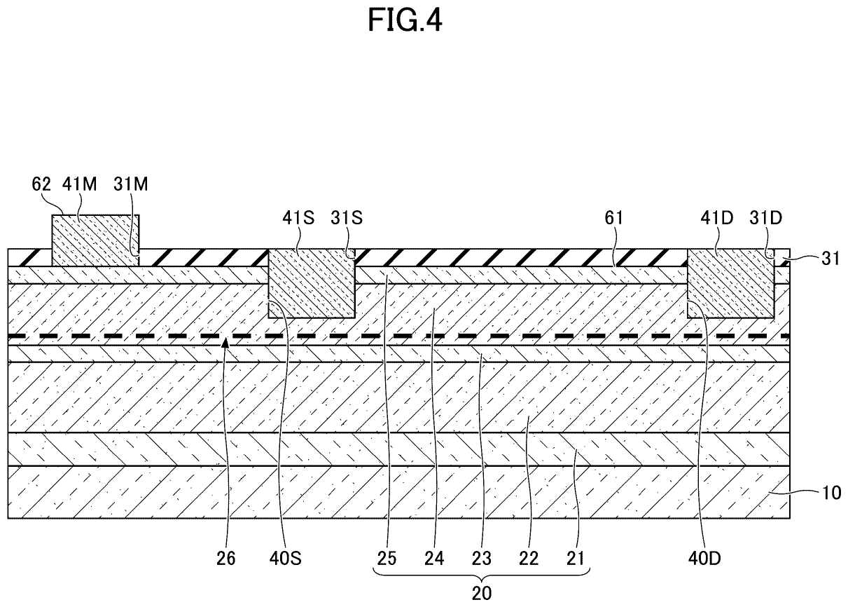

Next, as illustrated in FIG. 4, a regrown layer 41S is formed on the channel layer 24, the spacer layer 23, or the barrier layer 22 inside the opening 31S and the recess 40S, and a regrown layer 41D is formed on the channel layer 24, the spacer layer 23, or the barrier layer 22 inside the opening 31D and the recess 40D. In addition, a regrown layer 41M is formed on the upper surface 61 of the nitride semiconductor layer 20 inside the opening 31M. The regrown layer 41M has an upper surface 62 having a N polarity. The regrown layer 41S, the regrown layer 41D, and the regrown layer 41M can be formed simultaneously. The regrown layer 41S, the regrown layer 41D, and the regrown layer 41M are n-type GaN layers, for example. The regrown layer 41S, the regrown layer 41D, and the regrown layer 41M include germanium (Ge) or Si as an n-type impurity. Electrical resistances of the regrown layer 41S, the regrown layer 41D, and the regrown layer 41M are lower than an electrical resistance of the channel region 26. The regrown layer 41M has a thickness that is 5 nm or greater and 10 nm or less, for example. The regrown layer 41S, the regrown layer 41D, and the regrown layer 41M can be formed by MOCVD or MBE, for example. The regrown layer 41M is an example of a second nitride semiconductor layer, and the regrown layer 41S and the regrown layer 41D are examples of a third nitride semiconductor layer.

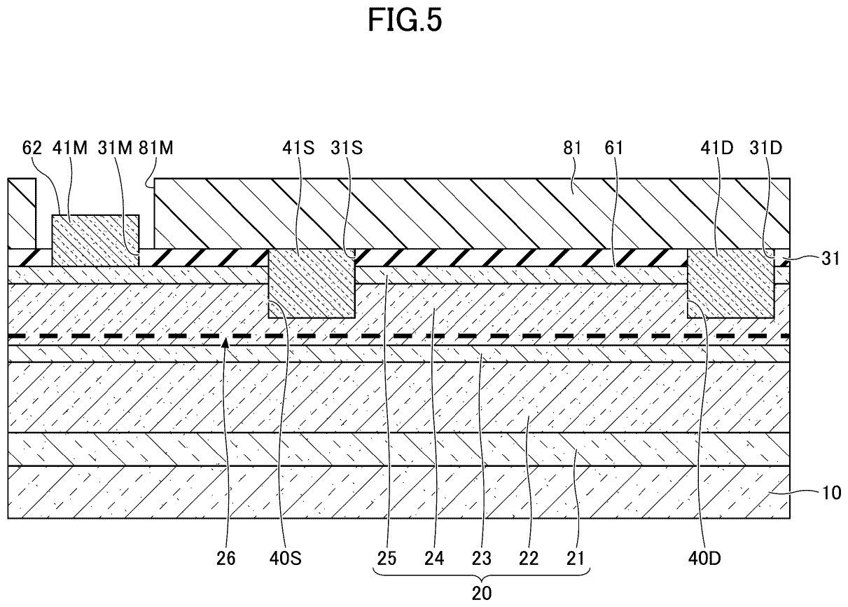

Next, as illustrated in FIG. 5, a mask 81, which covers the regrown layer 41S and the regrown layer 41D, and has an opening 81M exposing the regrown layer 41M, is formed on the insulating film 31, the regrown layer 41S, and the regrown layer 41D. A portion of the insulating film 31 may be exposed through the opening 81M.

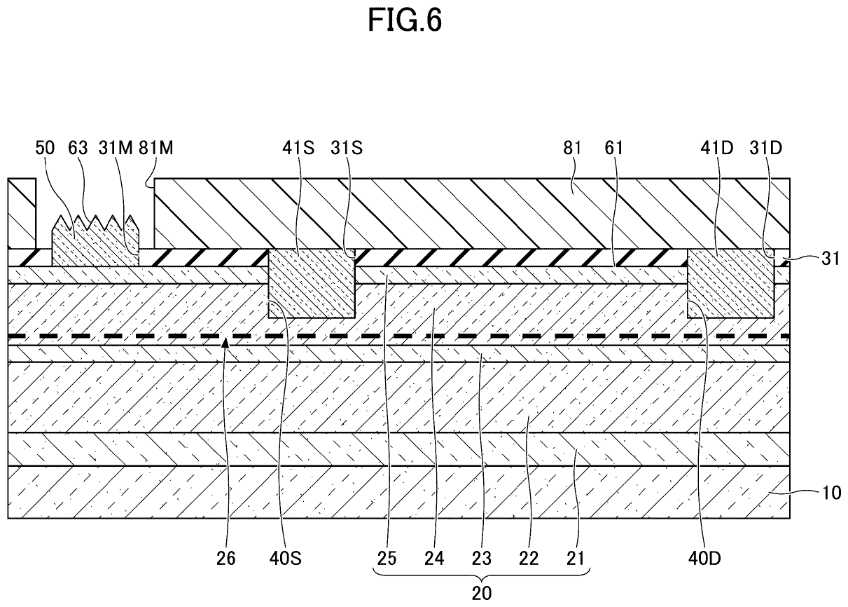

Next, the regrown layer 41M is subjected to a wet etching using an alkaline solution, so as to roughen the upper surface 62 of the regrown layer 41M and reduce a flatness of the upper surface. As a result, as illustrated in FIG. 6, an alignment mark 50 is formed from the regrown layer 41M. The alkaline solution used for the wet etching includes potassium hydroxide (KOH) having a temperature that is 26° C. or higher and 80° C. or lower, or tetramethylammonium hydroxide (TMAH) having a temperature that is 65° C. or higher and 100° C. or lower, for example. In a case where the regrown layer 41M is an n-type GaN layer, the upper surface 62 includes the (000-1) plane (−c plane) of gallium nitride. A (10-1-1) plane of GaN appears by subjecting the upper surface 62 to the wet etching. The (10-1-1) plane of GaN causes diffuse reflection reflects light L1 which will be described later, and functions as an alignment mark. That is, the alignment mark 50 has an upper surface 63 including the (10-1-1) plane of GaN.

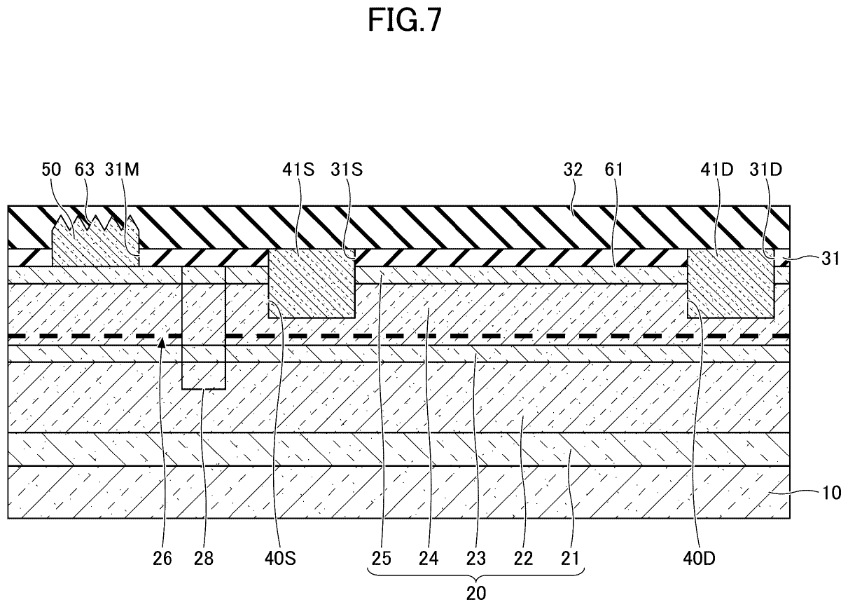

Next, as illustrated in FIG. 7, the mask 81 is removed. Further, an insulating film 32 is formed on the insulating film 31, the alignment mark 50, the regrown layer 41S, and the regrown layer 41D. The insulating film 32 can be formed by plasma CVD, for example. The insulating film 32 is a SiN film, for example. The insulating film 32 has a thickness that is 1 nm or more and 30 nm or less, for example. Next, an alignment is performed with reference to a position of the alignment mark 50, and ion implantation is locally performed to eliminate the channel region 26. Accordingly, an element isolation region 28 is formed in the nitride semiconductor layer 20.

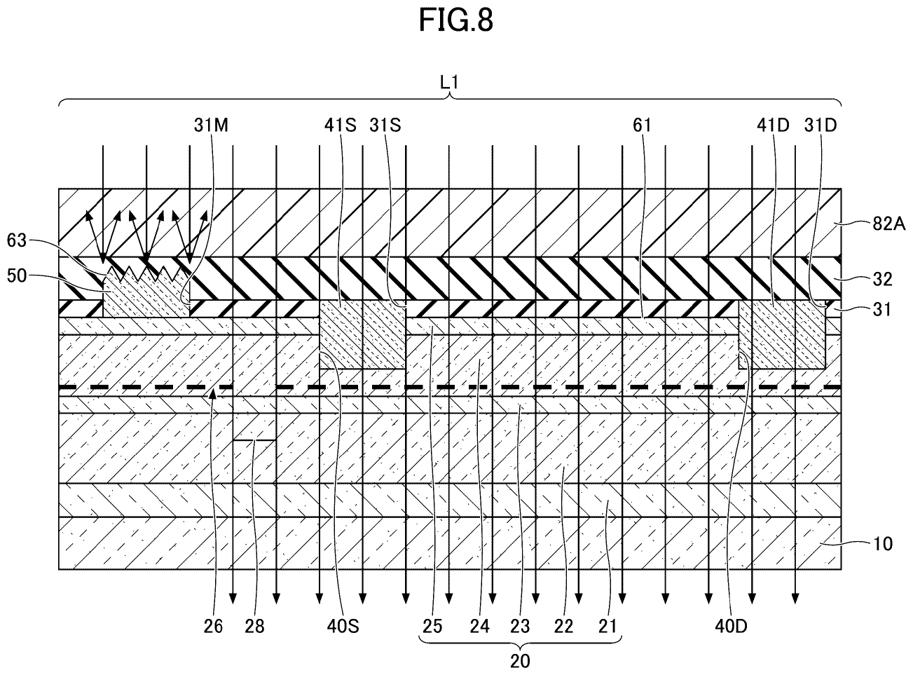

Next, as illustrated in FIG. 8, a positive photoresist layer 82A is formed on the insulating film 32. Further, the position of the alignment mark 50 is detected while irradiating the photoresist layer 82A with the light L1 having a wavelengths that is 546 nm or more and 547 nm or less (e-line (green mercury)). The diffuse reflection of the light L1 is caused by the upper surface 63 of the alignment mark 50, which is roughened, while the light L1 is transmitted through the photoresist layer 82A, the insulating film 32, the insulating film 31, the regrown layer 41S, the regrown layer 41D, the nitride semiconductor layer 20, and the substrate 10. Accordingly, the position of the alignment mark 50 can be detected with a high accuracy from the reflected light from the alignment mark 50. The wavelength that is 546 nm or grater and 547 nm or less is a wavelength band (or a wavelength range) in which a green light photoresist is substantially unexposed. The photoresist layer 82A is an example of a photosensitive film, and the light L1 is an example of first light.

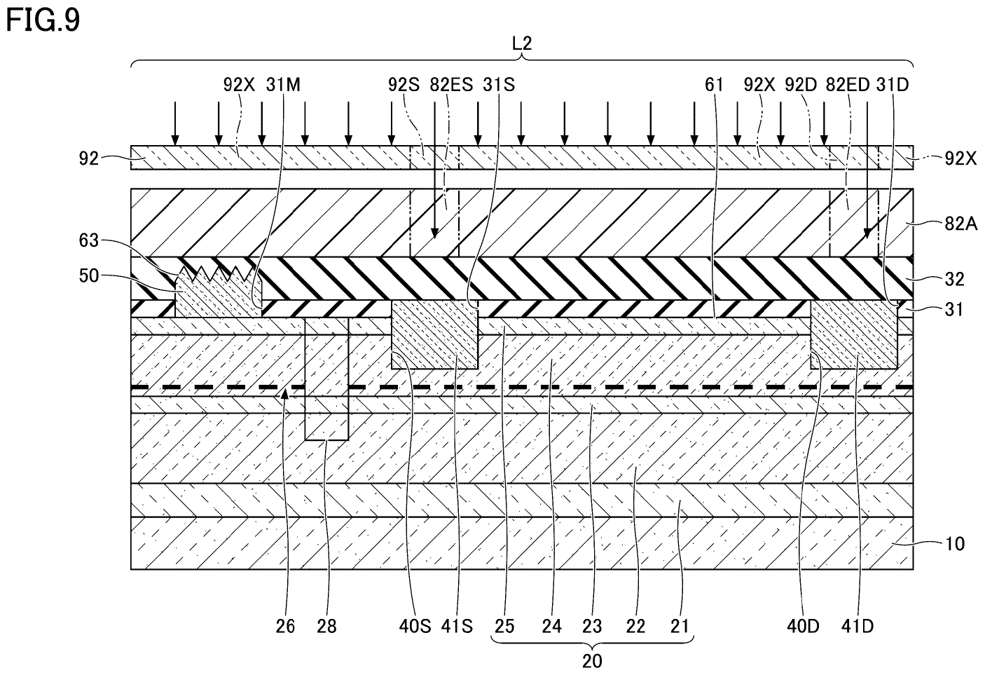

Next, as illustrated in FIG. 9, a photomask 92 is aligned with reference to the position of the alignment mark 50. The photomask 92 has a transparent area 92S for the source, a transparent area 92D for the drain, and an opaque area 92X other than these transparent areas 92S and 92D. Next, the photoresist layer 82A is irradiated with light L2 having a wavelength that is 365 nm or greater and 436 nm or less (i-line (ultraviolet mercury), h-line (violet mercury), and g-line (blue mercury)) through the photomask 92. That is, the light L2 is irradiated onto a portion of the photoresist layer 82A. As a result, a photosensitive region 82ES and a photosensitive region 82ED are formed in the photoresist layer 82A. The wavelength band that is 365 nm or greater and 436 nm or less is generally blue, violet, and ultraviolet light. The light L2 is an example of second light.

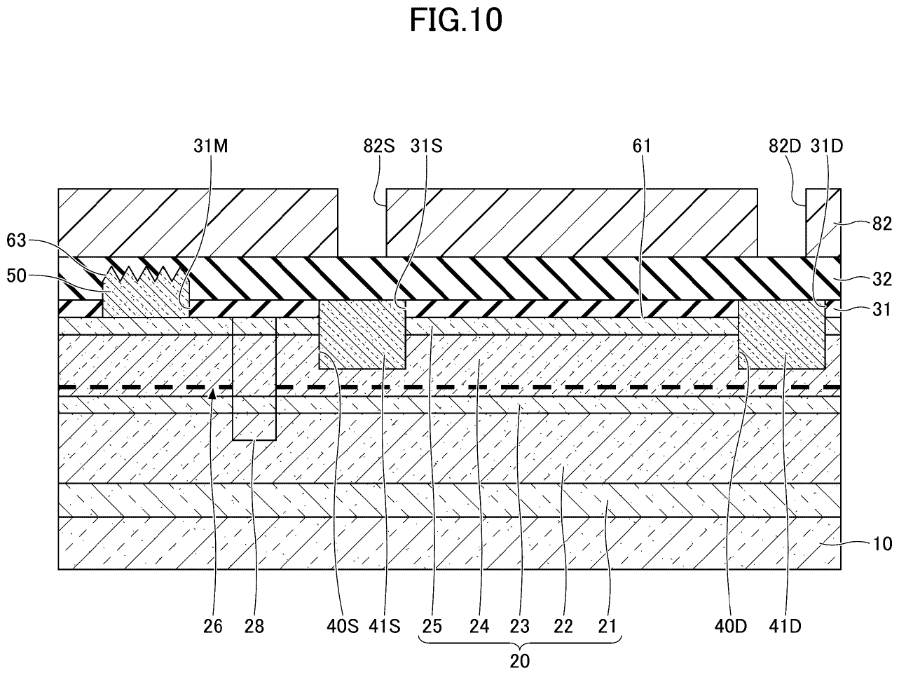

Next, as illustrated in FIG. 10, the photoresist layer 82A is developed to remove the photosensitive region 82ES and the photosensitive region 82ED, thereby forming a mask 82 having an opening 82S for the source and an opening 82D for the drain.

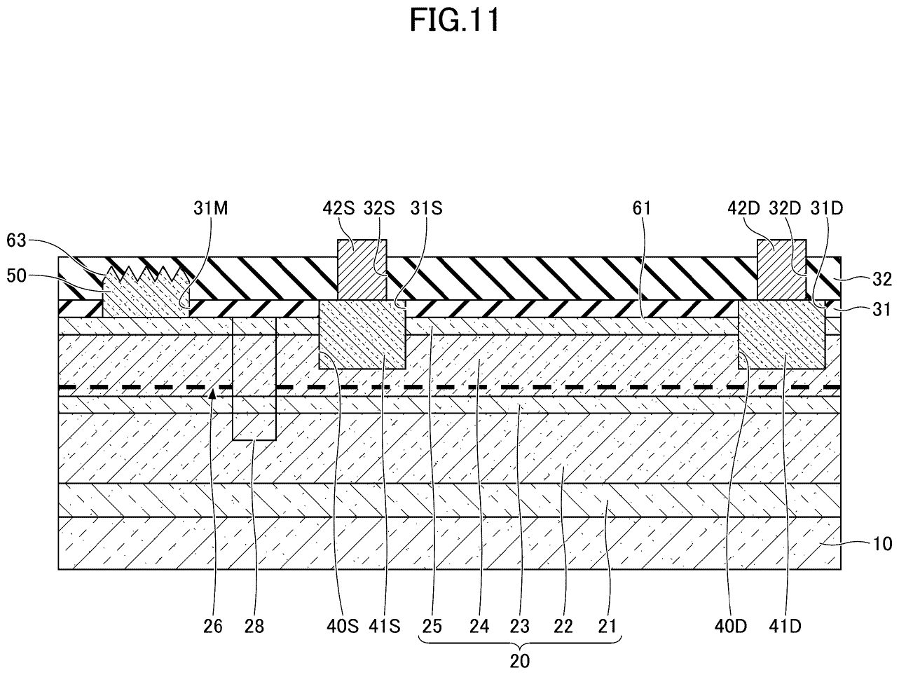

Next, as illustrated in FIG. 11, an opening 32S for the source and an opening 32D for the drain are formed in the insulating film 32 by RIE using the mask 82. Further, by forming a metal layer by vapor deposition or the like using the mask 82 and thereafter removing (lifting off) the mask 82, a source electrode 42S is formed on the regrown layer 41S inside the opening 32S, and a drain electrode 42D is formed on the regrown layer 41D inside the opening 32D.

Between the process of forming the openings 32S and 32D and the process of forming the metal layer, the mask 82 may be removed, and a mask having openings for the forming the source electrode 42S and the drain electrode 42D, formed with reference to the position of the alignment mark 50, may be newly formed from a photoresist layer. This photoresist layer is an example of a photosensitive film. The mask may include a plurality of photoresist layers.

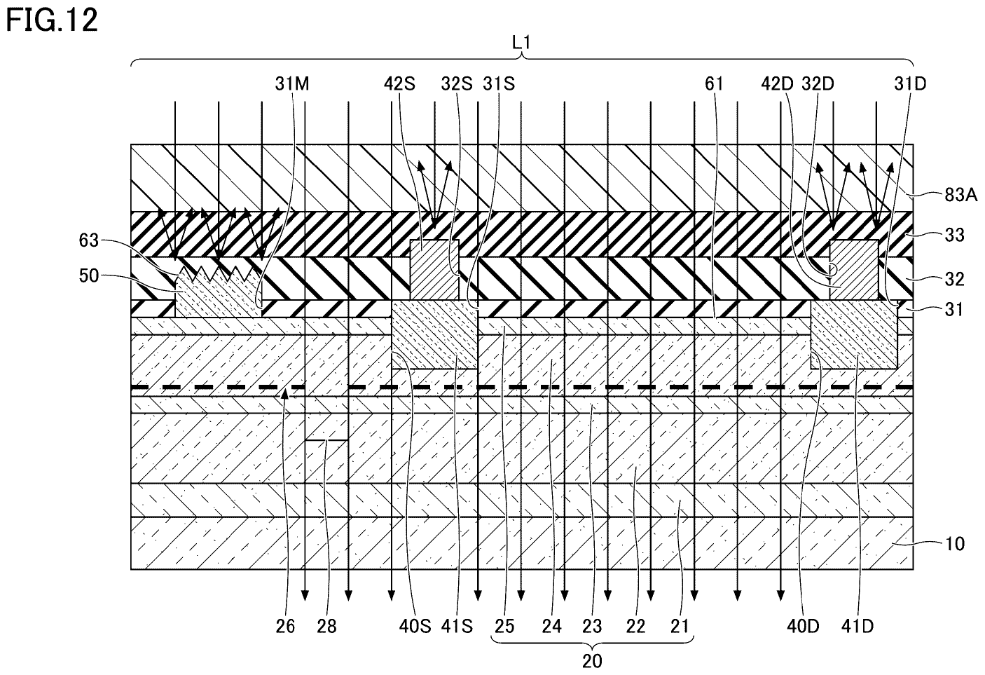

Next, as illustrated in FIG. 12, an insulating film 33 is formed on the insulating film 32, the source electrode 42S, and the drain electrode 42D. The insulating film 33 can be formed by plasma CVD, for example. The insulating film 33 is a SiN film, for example. The insulating film 33 has a thickness that is 1 nm or greater and 30 nm or less, for example.

Next, a positive photoresist layer 83A is formed on the insulating film 32. Further, the position of the alignment mark 50 is detected while the photoresist layer 83A is irradiated with the light L1. The diffuse reflection of the light L1 is caused by the upper surface 63 of the alignment mark 50, which is roughened, while the light L1 is transmitted through the photoresist layer 83A, the insulating film 33, the insulating film 32, the insulating film 31, the regrown layer 41S, the regrown layer 41D, the nitride semiconductor layer 20, and the substrate 10. Accordingly, in this case, the position of the alignment mark 50 can also be detected with a high accuracy from the reflected light from the alignment mark 50. The light L1 is also reflected by the source electrode 42S and the drain electrode 42D, but the alignment mark 50 can easily be distinguished from the source electrode 42S and the drain electrode 42D because forms of the reflection are different. The photoresist layer 83A is an example of a photosensitive film, and the light L1 is an example of first light.

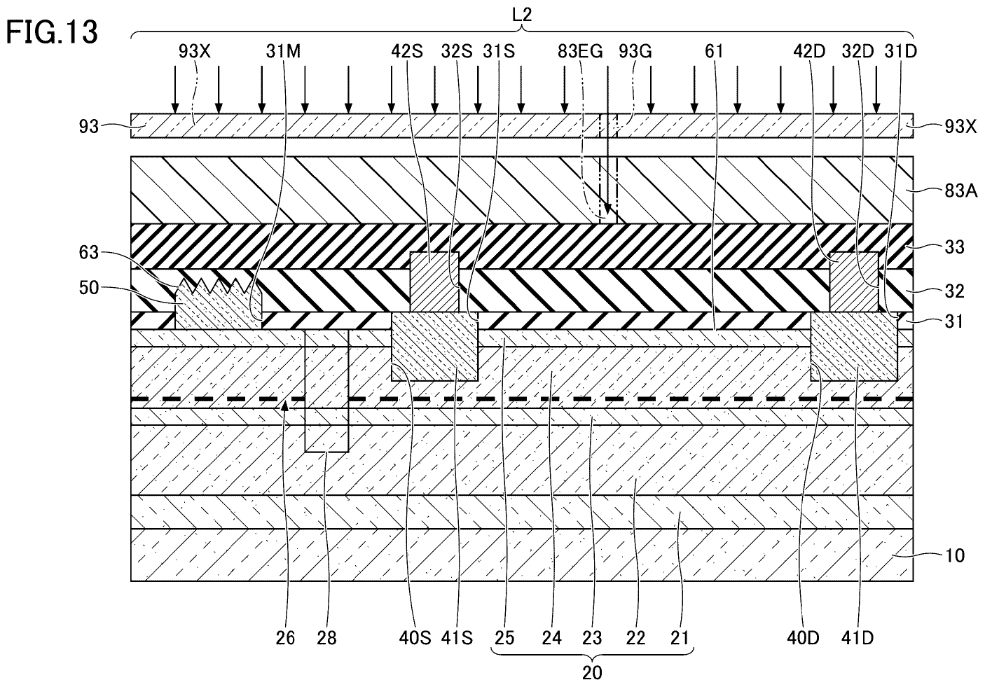

Next, as illustrated in FIG. 13, a photomask 93 is aligned with reference to the position of the alignment mark 50. The photomask 93 has a transparent area 93G for the drain, and an opaque area 93X other than the transparent area 93G. Next, the photoresist layer 83A is irradiated with light L2 through the photomask 93. That is, the light L2 is irradiated onto a portion of the photoresist layer 83A. As a result, a photosensitive region 83EG is formed in the photoresist layer 83A. The light L2 is an example of second light.

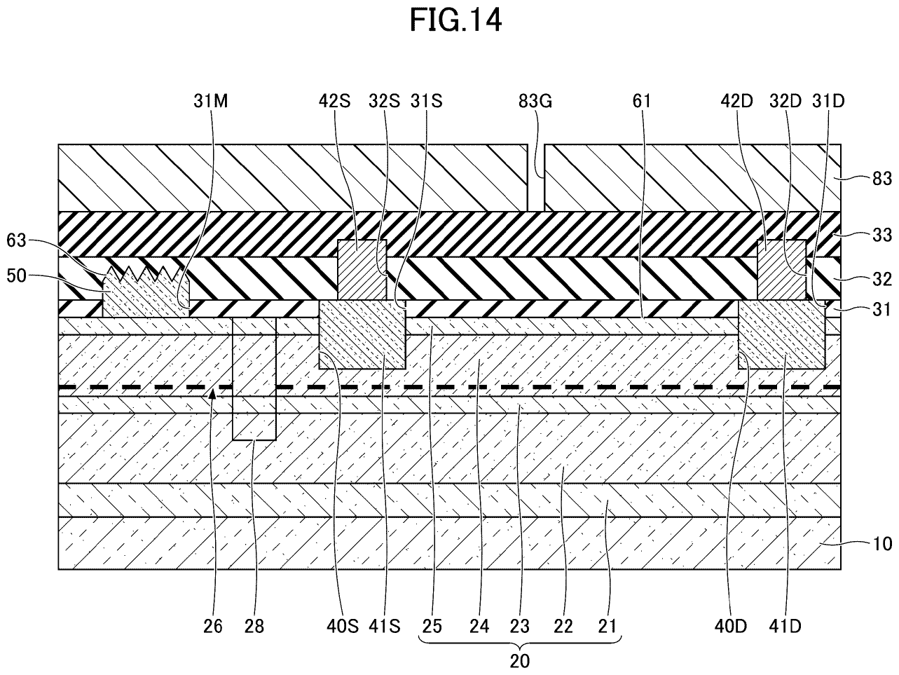

Next, as illustrated in FIG. 14, the photoresist layer 83A is developed to remove the photosensitive region 83EG, thereby forming a mask 83 having an opening 83G for a gate. An electron beam resist layer may be used in place of the photoresist layer 83A, and in this case, an electron beam may be used for exposure of the electron beam resist layer.

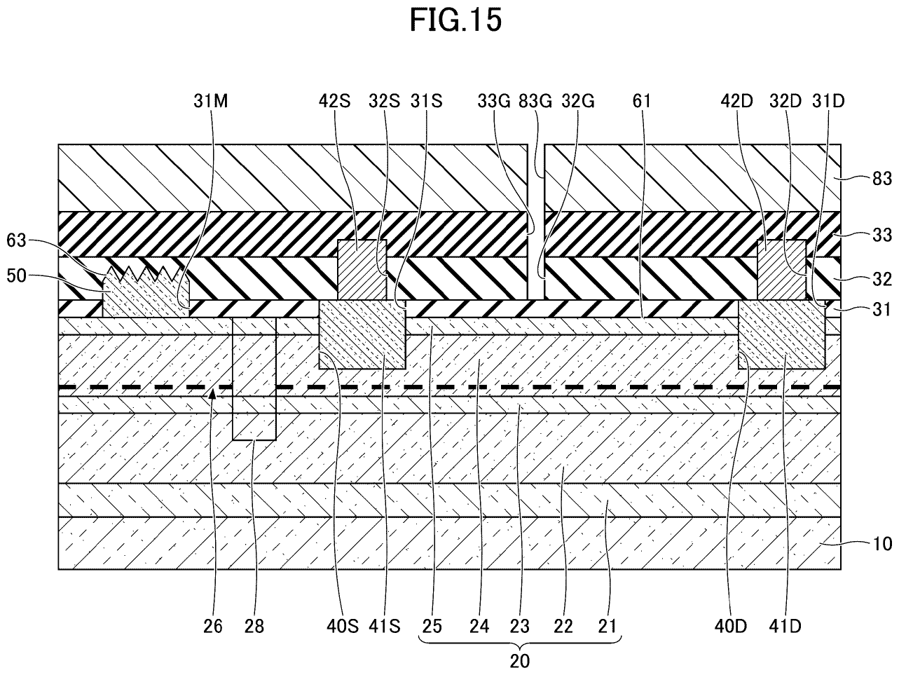

Next, as illustrated in FIG. 15, an opening 33G for the gate is formed in the insulating film 33 by RIE using the mask 83, and an opening 32G for the gate is formed in the insulating film 32.

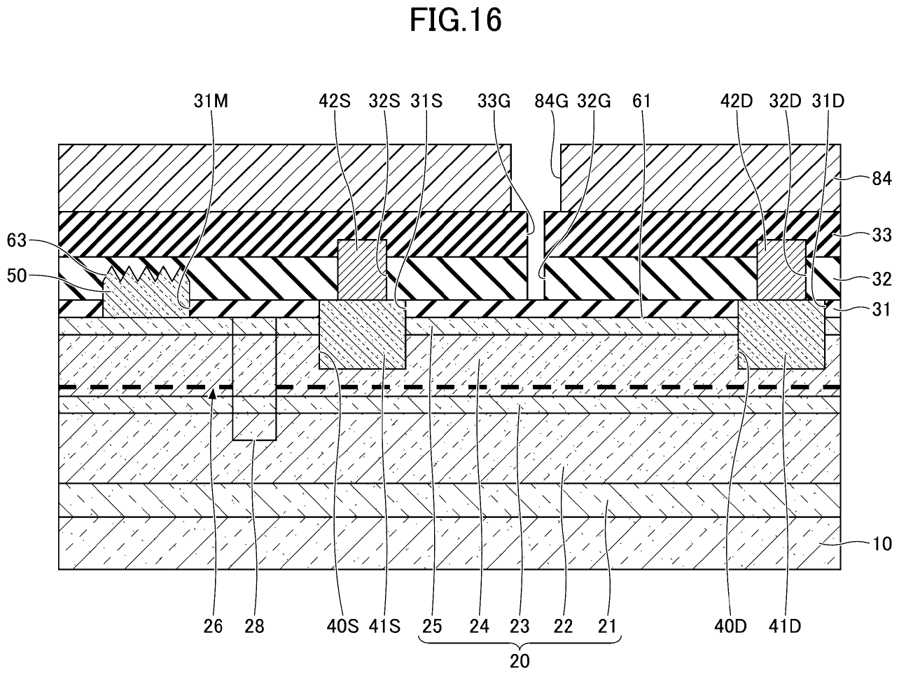

Next, as illustrated in FIG. 16, the mask 83 is removed, and a mask 84 having an opening 84G for the gate, formed with reference to the position of the alignment mark 50, is formed on the insulating film 33 from a photoresist layer. This photoresist layer is an example of a photosensitive film.

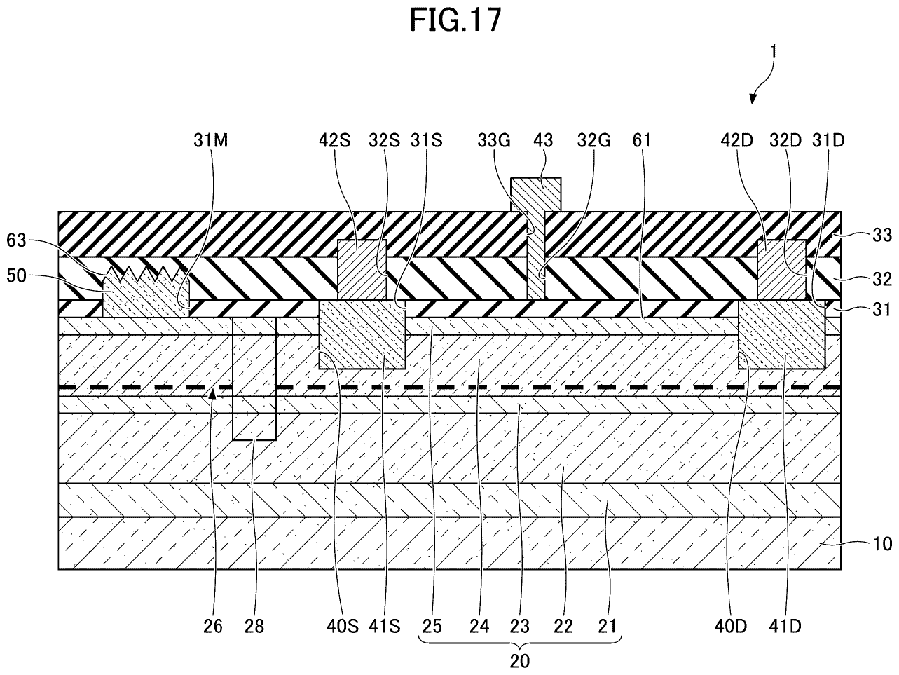

Next, as illustrated in FIG. 17, by forming a metal layer by vapor deposition or the like using the mask 84 and thereafter removing (lifting off) the mask 84, the gate electrode 43, in contact with the insulating film 31 through the opening 33G and the opening 32G, is formed on the insulating film 33.

The nitride semiconductor device 1 can be manufactured in the manner described above.

In the present embodiment, the upper surface 62 of the regrown layer 41M is roughened to form the alignment mark 50 having the roughened upper surface 63. The alignment mark 50 can easily be detected from the light reflected by the alignment mark 50, as long as the layer formed on the alignment mark 50 can transmit the light L1 used for detecting the alignment mark 50. Hence, the position of the common alignment mark 50 can be used as a reference, in a case where the alignment is performed a plurality of times to form a plurality of constituent elements included in the nitride semiconductor device 1. For this reason, it is possible to improve the alignment accuracy among the plurality of constituent elements. For example, it is possible to improve the alignment accuracy between the source electrode 42S and each of the drain electrode 42D and the gate electrode 43.

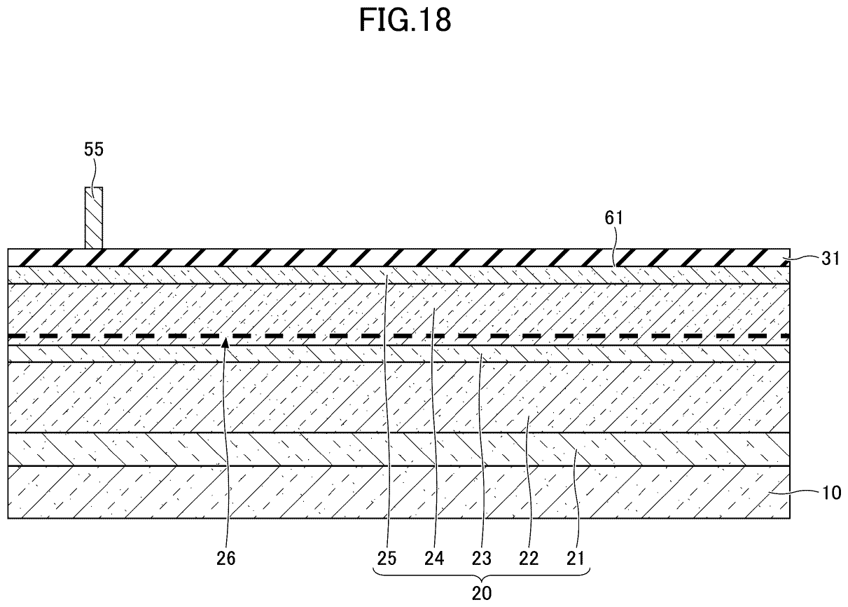

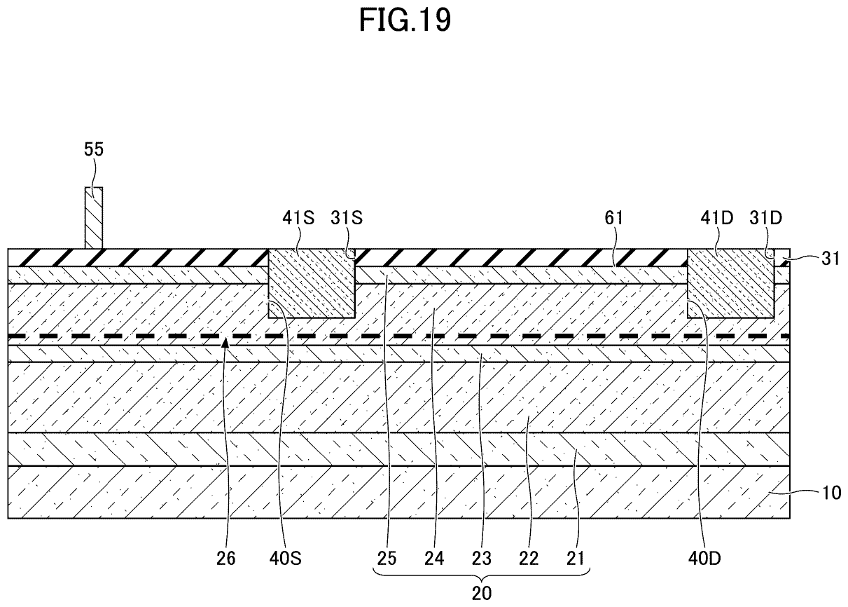

Although it is conceivable to use a metal alignment mark as an alignment mark that is easy to detect, the metal alignment mark is unsuitable for use in manufacturing the nitride semiconductor device, as will be described below. FIG. 18 and FIG. 19 are cross sectional views illustrating a method for manufacturing the nitride semiconductor device using the metal alignment mark.

Even in the case where the metal alignment mark is used, the processes up to forming the insulating film 31 are performed as in the embodiment described above (refer to FIG. 2). Next, as illustrated in FIG. 18, a metal alignment mark 55 is formed on the insulating film 31.

Next, as illustrated in FIG. 19, with reference to the position of the alignment mark 55, the opening 31S and the opening 31D are formed in the insulating film 31, and the recess 40S and the recess 40D are formed in the nitride semiconductor layer 20. Next, the regrown layer 41S is formed on the channel layer 24, or the spacer layer 23, or the barrier layer 22 inside the opening 31S and the recess 40S, and the regrown layer 41D is formed on the channel layer 24, or the spacer layer 23, or the barrier layer 22 inside the opening 31D and the recess 40D.

However, when the regrown layer 41S and the regrown layer 41D are formed in a state where the alignment mark 55 is exposed, the inside of a growth reactor used for forming the regrown layer 41S and the regrown layer 41D may become contaminated by the metal included in the alignment mark 55. Accordingly, the regrown layer 41S and the regrown layer 41D cannot be formed in the state where the alignment mark 55 is exposed. Although it is possible to prevent the metal contamination by covering the alignment mark 55 with a transparent film, additional processes are required to form and remove the transparent film.

As described above, the metal alignment mark is unsuitable for use in manufacturing the nitride semiconductor device. On the other hand, in the manufacturing method according to the present embodiment, there is no possibility contaminating the inside of the growth reactor. Further, no additional processes are required to form the opening 31M and to form the regrown layer 41M.

By exposing the photoresist layer 82A and forming the photosensitive regions 82ES and 82ED with reference to the position of the alignment mark 50 detected by irradiating the photoresist layer 82A with the light L1, it is possible to form the photosensitive regions 82ES and 82ED with a high alignment accuracy. In addition, by exposing the photoresist layer 83A and forming the photosensitive region 83EG with reference to the position of the alignment mark 50 detected by irradiating the photoresist layer 83A with the light L1, it is possible to form the photosensitive region 83EG with a high alignment accuracy.

For example, the wavelength of the light L1 is 546 nm greater and 547 nm or less, and the wavelength of the light L2 is 365 nm or greater and 436 nm or less. In this case, the position of the alignment mark 50 can be detected without exposing the photoresist layers 82A and 83A to the light L1, and thereafter, the photosensitive regions 82ES and 82ED can be formed in the photoresist layer 82A and the photosensitive region 83EG can be formed in the photoresist layer 83A, using the light L2. The wavelength of the light L2 may be 365 nm or greater and 366 nm or less, or 404 nm or greater and 405 nm or less, or 435 nm or greater and 436 nm or less.

When the regrown layer 41M is a GaN layer, the regrown layer 41M can easily be formed. When the alignment mark 50 is formed from a GaN layer, the upper surface 63 of the alignment mark 50 is likely to include the (000-1) plane (−c plane) of GaN. Further, when the alkaline solution includes potassium hydrate or tetramethylammonium hydrate, the upper surface 62 of the regrown layer 41M can easily be roughened.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a nitride semiconductor device comprising:
forming an insulating film having a first opening on an upper surface of a first nitride semiconductor layer, the upper surface having a nitrogen polarity;
forming a second nitride semiconductor layer on the upper surface inside the first opening; and
forming an alignment mark by roughening an upper surface of the second nitride semiconductor layer by a wet etching using an alkaline solution.

2. The method for manufacturing the nitride semiconductor device as claimed in claim 1, further comprising:
forming a photosensitive film on the insulating film and the alignment mark;
irradiating the photosensitive film with first light and detecting a position of the alignment mark from reflected light from the alignment mark; and
forming a photosensitive region by irradiating a portion of the photosensitive film with second light, with reference to the detected position of the alignment mark.

3. The method for manufacturing the nitride semiconductor device as claimed in claim 2, wherein:
the first light has a wavelength of 546 nm or more and 547 nm or less, and
the second light has a wavelength of 365 nm or more and 436 nm or less.

4. The method for manufacturing the nitride semiconductor device as claimed in claim 1, wherein the second nitride semiconductor layer is a gallium nitride layer.

5. The method for manufacturing the nitride semiconductor device as claimed in claim 4, wherein the alignment mark has an upper surface including a (10-1-1) plane of gallium nitride.

6. The method for manufacturing the nitride semiconductor device as claimed in claim 1, wherein the alkaline solution includes potassium hydroxide or tetramethylammonium hydroxide.

7. The method for manufacturing the nitride semiconductor device as claimed in claim 1, wherein the insulating film has a second opening, and further comprising:
forming a third nitride semiconductor layer inside the second opening simultaneously as forming the second nitride semiconductor layer.

8. The method for manufacturing the nitride semiconductor device as claimed in claim 2, wherein the second nitride semiconductor layer is a gallium nitride layer.

9. The method for manufacturing the nitride semiconductor device as claimed in claim 8, wherein the alignment mark has an upper surface including a (10-1-1) plane of gallium nitride.

10. The method for manufacturing the nitride semiconductor device as claimed in claim 3, wherein the second nitride semiconductor layer is a gallium nitride layer.

11. The method for manufacturing the nitride semiconductor device as claimed in claim 10, wherein the alignment mark has an upper surface including a (10-1-1) plane of gallium nitride.
